(19) United States
(12) Patent Application Publication
(10) Pub. No.: US 2008/0074118 A1
(43) Pub. Date: Mar. 27, 2008

(54) Pick-And-Place Mechanism Of Electronic Device, Electronic Device Handling Apparatus And Suction Method Of Electronic Device

(75) Inventor: Yoshiyuki Masuo, Tokyo (JP)

Correspondence Address: POSZ LAW GROUP, PLC, 12040 SOUTH LAKES DRIVE, SUITE 101, RESTON, VA, 20191, US

(73) Assignee: ADVANTEST CORPORATION, Tokyo (JP)

(21) Appl. No.: 11/887,619

(22) PCT Filed: Apr. 7, 2005
(86) PCT No.: PCT/JP2005/006860

§ 371 Date: Oct. 18, 2007

(51) Int. Cl. G01R 31/02; B23P 19/00

(52) U.S. Cl. 324/537; 29/742; 29/743

(57) ABSTRACT

A translatory type actuator 503 for moving a support member 502 supporting the suction head 501 up and down between an upper stroke end and a lower stroke end; and a servo actuator 504 for lowering the support member 502 and the suction head 501 together with the translatory type actuator 503 while controlling a speed thereof in a state that the support member 502 is at the lower stroke end so as to bring the suction head 501 contact with an electronic device 2; are included. According to this pick-and-place mechanism 500, an impact load acting on an electronic device 2 at the time of picking up the electronic device 2 by the suction head 501 can be reduced as much as possible.

### TECHNICAL FIELD

The present invention relates to a pick-and-place mechanism of an electronic device, an electronic device handling apparatus and a suction method of an electronic device.

### BACKGROUND ART

In a production procedure of an electronic device, such as an IC device, an electronic device testing apparatus for testing performance and functions of a finally produced IC device and devices in the intermediate stages becomes necessary. In such an electronic device testing apparatus, IC devices held on a customer tray are reloaded to a test tray, the plurality of IC devices loaded on the test tray are handled and subjected to a test and, then, the post-test IC devices are reloaded from the test tray to predetermined customer trays in accordance with the test results.

When reloading the IC devices from a customer tray to a test tray or from the test tray to the customer tray, a pick-and-place mechanism is used, which is capable of picking up the IC devices by suction by suction heads, moving them to predetermined positions and, then, loading.

As the pick-and-place mechanism, for example, as shown in FIG. 13, those which move a piston rod 502P supporting a suction head 501P up and down by a cylinder device 503P may be mentioned. According to the pick-and-place mechanism, as shown in FIG. 14, the piston rod 502P is lowered to the lower end of a certain stroke width by the cylinder device 503P, and an upper surface of an IC device 2P is sucked by the suction head 501P to be elevated.

As another example of a pick-and-place mechanism, as shown in FIG. 15 and FIG. 16, those which move the suction pad 501P up and down by a screw mechanism 504P using a ball screw may be mentioned. According to the pick-and-place mechanism, by converting a rotation movement of a drive motor 505P to a linear movement, the suction pad 501P is moved up and down so as to be able to pick up the IC device 2P and load on a predetermined position.

### DISCLOSURE OF THE INVENTION

### Problem to be Solved by the Invention

In the case of the conventional pick-and-place mechanisms shown in FIG. 13 and FIG. 14, however, although the structure is simplified due to a mechanism of moving the piston rod 502P and the suction head 501P up and down by using the cylinder device 503P, there is a disadvantage that the piston rod 502P basically can stop only at two positions: the upper stroke end and the lower stroke end. Namely, only two-position control is possible by the pick-and-place mechanisms, and position control of the piston rod 502P or acceleration/deceleration of the piston rod 501P is difficult. Therefore, a thrust force of the cylinder device 503P as it is easily acts on an IC device 2P. As a result, an impact load is imposed when the suction pad 501P contacts the IC device 2P.

On the other hand, in the case of the pick-and-place mechanism shown in FIG. 15 and FIG. 16, there is an advantage that an impact load at the time that the suction pad 501P contacts the IC device 2P can be reduced by controlling to adjust a rotation speed of the drive motor 505P. However, particularly when handling a plurality of IC devices 2P simultaneously, such a pick-and-place mechanism is liable to become complicated in the structure and in need of a larger installment space. Furthermore, since many expensive parts are used, an increase of costs is also inevitable.

The present invention was made in consideration of the above circumstances and has as an object thereof to provide a pick-and-place mechanism of an electronic device, an electronic device handling apparatus and a suction method of an electronic device, by which an impact load acting on an electronic device can be reduced as much as possible when picking up the electronic device by suction by a suction head and a simple and inexpensive structure can be realized even in the case of handling a plurality of electronic devices simultaneously.

### Means for Solving the Problem

To attain the above object, firstly, the present invention provides a pick-and-place mechanism of an electronic device for picking up an electronic device by suction by a suction head, moving the same and, then, placing the same at a predetermined position in an electronic device testing apparatus, comprising a translatory type actuator for moving a support member supporting the suction head up and down between an upper stroke end and a lower stroke end; and a servo actuator for moving the support member and the suction head together with the translatory type actuator up and down and capable of controlling a speed of at least an operation in the downward direction (an invention 1).

According to the above invention (the invention 1), when bringing the suction head contact with an electronic device, the support member and the suction head supported thereby can be lowered by the servo actuator while controlling the speed. Accordingly, by sufficiently reducing the lowering speed of the support member and the suction head at the time of contacting, an impact acting on the electronic device at the time that the suction head contacts the electronic device can be reduced as much as possible.

In the above invention (the invention 1), preferably, the servo actuator operates to bring the suction head contact with the electronic device by lowering the support member and the suction head together with the translatory type actuator while controlling the speed in a state that the support member is positioned at a lower stroke end (an invention 2).

In the above invention (the invention 1), the pick-and-place mechanism of an electronic device preferably comprises a plurality of the suction heads (an invention 3). Since a plurality of suction heads can be moved up and down simultaneously by operating one servo actuator, it is possible to pick and place a plurality of electronic devices at one time.

In the above invention (the invention 3), preferably, the support member and the translatory type actuator are provided to each of the plurality of suction heads (an invention 4). In that case, in addition to moving all suction heads up and down simultaneously by the servo actuator, the respective suction heads can be moved up and down separately by the translatory type actuators. Also, a servo actuator, for example, a servo actuator using a ball screw generally has a complicated structure, requires a wide installment space, and is expensive, so that when controlling a plurality of suction heads respectively by a plurality of servo actuators, that results in an increase in size and a marked increase in costs. However, according to the above invention (the invention 3), one servo actuator is sufficient, so that a simple and inexpensive structure can be realized.

In the above invention (the invention 1), preferably, the support member is a piston rod, and the translatory type actuator is a cylinder device which makes the piston rod move back and forth (an invention 5). A cylinder device as such is compact and inexpensive, so that the pick-and-place mechanism can be downsized and low at cost. Also, since the cylinder device is generally capable of driving at a high speed, moving time of the suction head can become shorter comparing with that in the case of using only a servo actuator.

In the above invention (the invention 1), the servo actuator comprises a ball screw and a motor for driving the ball screw (an invention 6). According to the ball screw, highly accurate position control and speed control become possible, so that it becomes possible to reduce an impact load acting on an electronic device at the time of picking up the electronic device by suction by the suction head as much as possible.

Secondary, the present invention provides an electronic device handling apparatus capable of handling an electronic device for conducting tests on the electronic device, comprising the above explained pick-and-place mechanism (the inventions 1 to 6) (an invention 7).

Thirdly, the present invention provides a suction method of an electronic device when picking up an electronic device by suction by a suction head in an electronic device testing apparatus, comprising steps of: setting a position of a lower stroke end of a support member, which supports the suction head and is capable of moving straight, at a position where the suction head stops short of the electronic device; lowering the support member to the lower stroke end by a translatory actuator; then, bringing the suction head contact with the electronic device while reducing an impact at the time of contacting by lowering the support member and the suction head together with the translatory type actuator by a servo actuator while controlling the speed; and picking up the electronic device by the suction head (an invention 8).

Fourthly, the present invention provides a suction method of an electronic device when picking up an electronic device by suction by a suction head in an electronic device testing apparatus, comprising steps of: setting a position of a lower stroke end of a piston rod, which supports the suction head, at a position where the suction head stops short of the electronic device; lowering the piston rod to the lower stroke end by a cylinder device; then, bringing the suction head contact with the electronic device while reducing an impact at the time of contacting by lowering the piston rod and the suction head together with the cylinder device by a ball screw while controlling the speed; and picking up the electronic device by the suction head (an invention 9).

According to the above inventions (the inventions 8 and 9), at the time of bringing the suction head contact with an electronic device, the support member and the suction head supported thereby can be lowered while controlling the speed by the servo actuator (ball screw), therefore, an impact acting on the electronic device at the time that the suction head contacts with the electronic device can be reduced as much as possible by sufficiently reducing the lowering speed of the support member and the suction head at the time of contacting.

Fifthly, the present invention provides a pick-and-place mechanism of an electronic device capable of picking up an electronic device by suction and mounting at a predetermined position by a suction head in an electronic device testing apparatus, comprising: a first drive mechanism which supports the suction head and is capable of moving the suction head to a first position, where the electronic device is picked up by suction or mounted, and to a second position being away from the first position; and a second drive mechanism which supports the first drive mechanism and is capable of successively moving the first drive mechanism by a predetermined move amount and stopping the same (an invention 10).

According to the above invention (the invention 10), at the time of bringing the suction head contact with an electronic device, a move amount and a stop position of the suction head supported by the first drive mechanism can be controlled by the second drive mechanism. Accordingly, by setting the stop position of the suction head at the time of contacting with the electronic device to be an optimal position, an impact acting on the electronic device at the time that the suction head contacts with the electronic device can be reduced as much as possible.

In the above invention (the invention 10), preferably, the first drive mechanism is a translatory type actuator capable of stroke moving the suction head between a lower stroke end as the first position and an upper stroke end as the second position (an invention 11), and the second drive mechanism is preferably a servo actuator having a drive axis, and the first drive mechanism is attached to a drive axis of the second drive mechanism (an invention 12).

In the above invention (the invention 10), preferably, there are a plurality of the first drive mechanisms, the second drive mechanism supports the plurality of first drive mechanisms, and the plurality of first drive mechanisms can move simultaneously by driving the second drive mechanism (an invention 13).

In the above invention (the invention 10), preferably, the suction head or a tube path for drawing connected to the suction head is provided with a suction detection sensor capable of detecting whether an electronic device is picked up by the suction head or not; the pick-and-place mechanism is driven to pick up an electronic device by suction by the suction head, the suction detection sensor specifies a position where suction of the electronic device is detected, and a stop position of the second drive mechanism can be set based on the specified detection position (an invention 14).

According to the above invention (the invention 14), the stop position of the second drive mechanism at the time of contacting with the electronic device and, moreover, a stop position of the suction head can be automatically set to be optimal positions.

Sixthly, the present invention provides an electronic device testing apparatus comprising a pick-and-place mechanism of an electronic device capable of picking up an electronic device by suction and mounting the same at a predetermined position by a suction head, wherein the pick-and-place mechanism comprises a first drive mechanism which supports the suction head and is capable of moving the suction head to a first position, where the electronic device is picked up by suction or mounted, and to a second position being away from the first position; and a second drive mechanism which supports the first drive mechanism and is capable of successively moving the first drive mechanism by a predetermined move amount and stopping the same (an invention 15).

### ADVANTAGEOUS EFFECT OF THE INVENTION

According to the pick-and-place mechanism of an electronic device, the electronic device handling apparatus or the suction method of an electronic device of the present invention, at the time of picking up an electronic device by suction by a suction head, an impact load acting on the electronic device can be reduced as much as possible. Furthermore, it is possible to realize a simple and inexpensive structure even when handling a plurality of electronic devices simultaneously.

### BRIEF DESCRIPTION OF DRAWINGS

FIG. 1 is an overall view form the side of an IC device testing apparatus including a handler according to an embodiment of the present invention.

FIG. 2 is a perspective view of the handler.

FIG. 3 is a flowchart of trays showing a handling method of IC devices to be tested.

FIG. 4 is a perspective view showing a customer tray used in the handler.

FIG. 5 is a sectional view of a key part inside a test chamber in the handler.

FIG. 6 is a partially disassembled perspective view of a test tray used in the handler.

FIG. 7 is a view from the side of an example of a pick-and-place mechanism according to an embodiment of the present invention.

FIG. 8 is a view from the side showing the pick-and-place mechanism shown in FIG. 7 in a state that a translatory type actuator is activated to lower a suction head to a lower stroke end.

FIG. 9 is a view from the side showing the pick-and-place mechanism shown in FIG. 8 in a state that a servo actuator is activated to lower the suction head together with the translatory type actuator and the suction head is brought to contact with an electronic device.

FIG. 10 is a view from the side showing the pick-and-place mechanism shown in FIG. 8 in a state that the servo actuator is activated to lower the suction head together with the translatory type actuator and the suction head is brought to contact with an electronic device.

FIG. 11 is a view from the side showing an example of a pick-and-place mechanism provided with a plurality of suction heads and translatory type actuators.

FIG. 12 is a view from the above showing an example of a pick-and-place mechanism provided with a plurality of suction heads and translatory type actuators.

FIG. 13 is a view from the side showing a conventional pick-and-place mechanism configured to move a piston rod supporting a suction head up and down by a cylinder device.

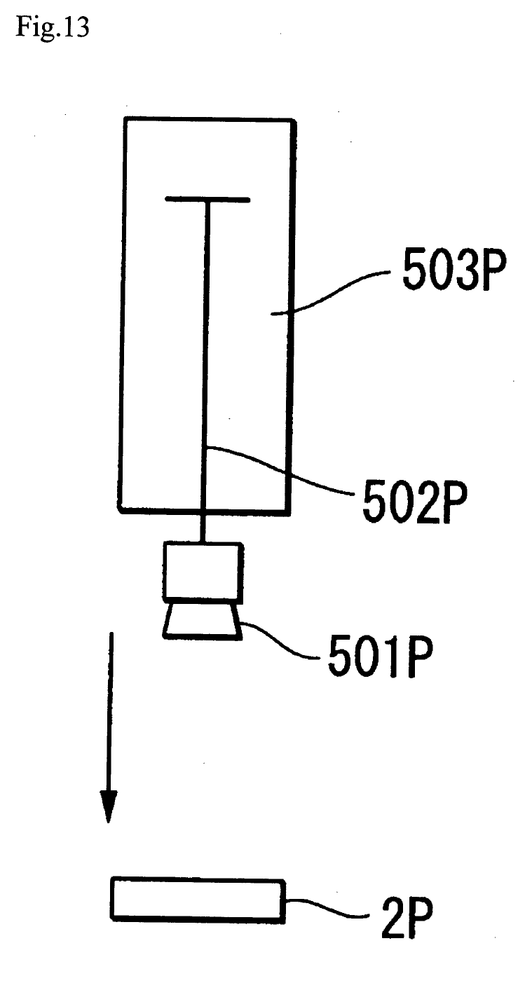

FIG. 14 is a view from the side of the conventional pick-and-place mechanism shown in FIG. 13 in a state that a suction head is brought to contact with an IC device.

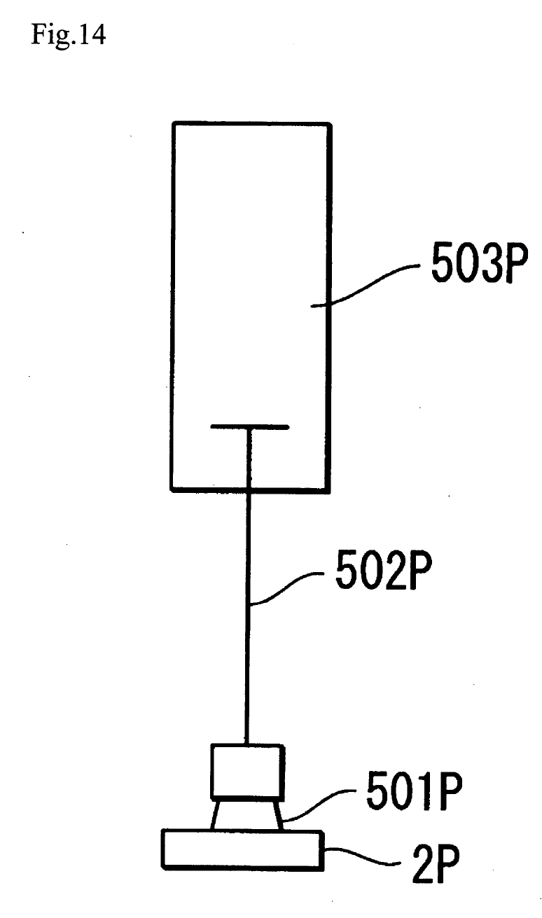

FIG. 15 is a view from the side showing a conventional pick-and-place mechanism configured to move a suction head up and down by a screw mechanism using a ball screw.

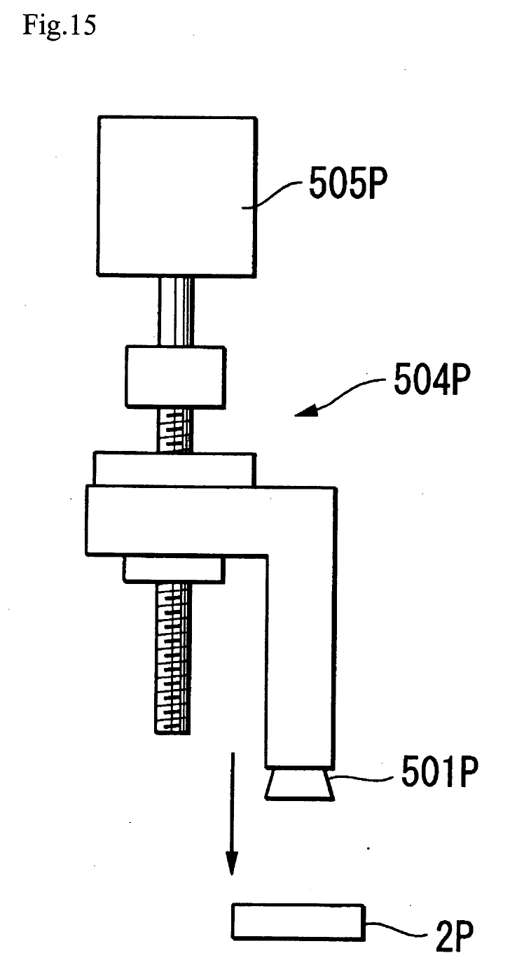

FIG. 16 is a view from the side of the conventional pick-and-place mechanism shown in FIG. 15 in a state that the suction head is brought to contact with an IC device.

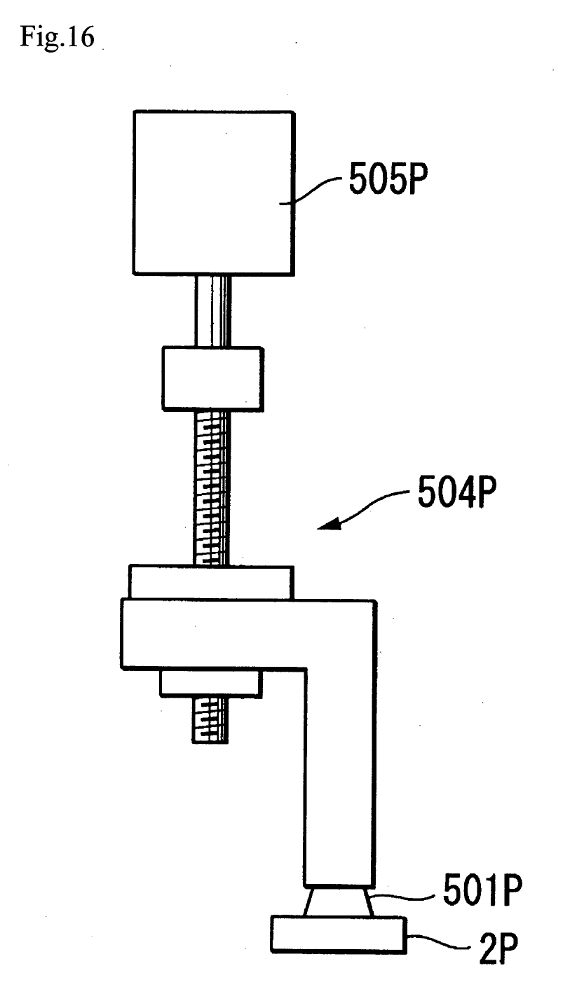

### EXPLANATION OF REFERENCES

1 . . . electronic device handling apparatus (handler)
10 . . . IC device (electronic device) testing apparatus
500 . . . pick-and-place mechanism
501 . . . suction head
502 . . . piston rod (support member)
503 . . . cylinder device (translatory type actuator)
504 . . . ball screw (servo actuator)
505 . . . drive motor

### BEST MODE FOR CARRYING OUT THE INVENTION

Below, an embodiment of the present invention will be explained in detail based on the drawings.

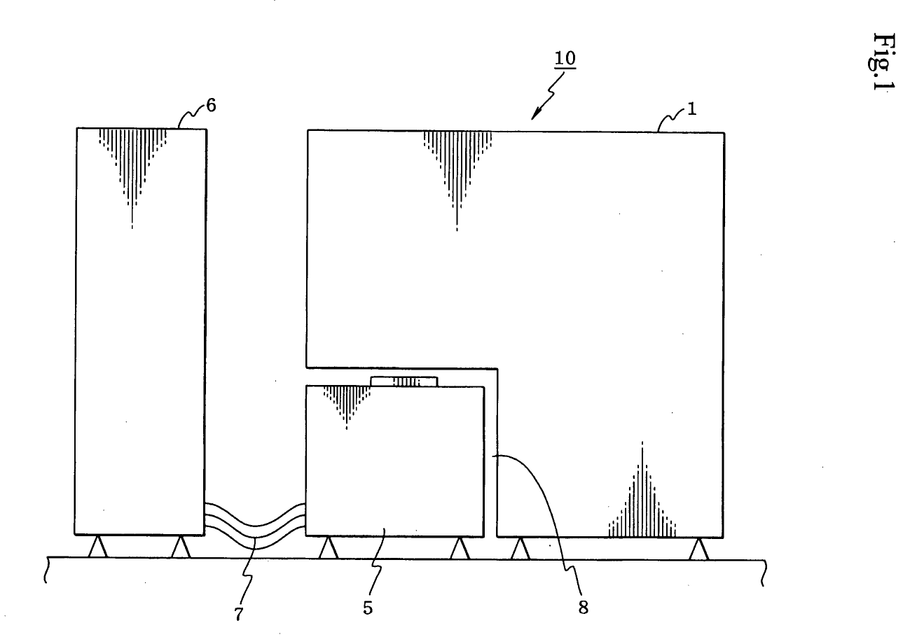

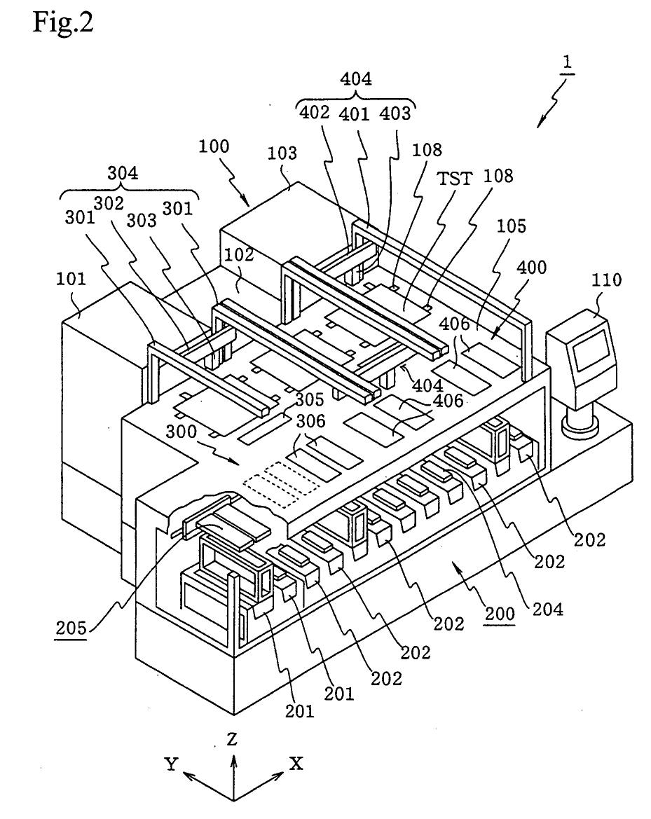

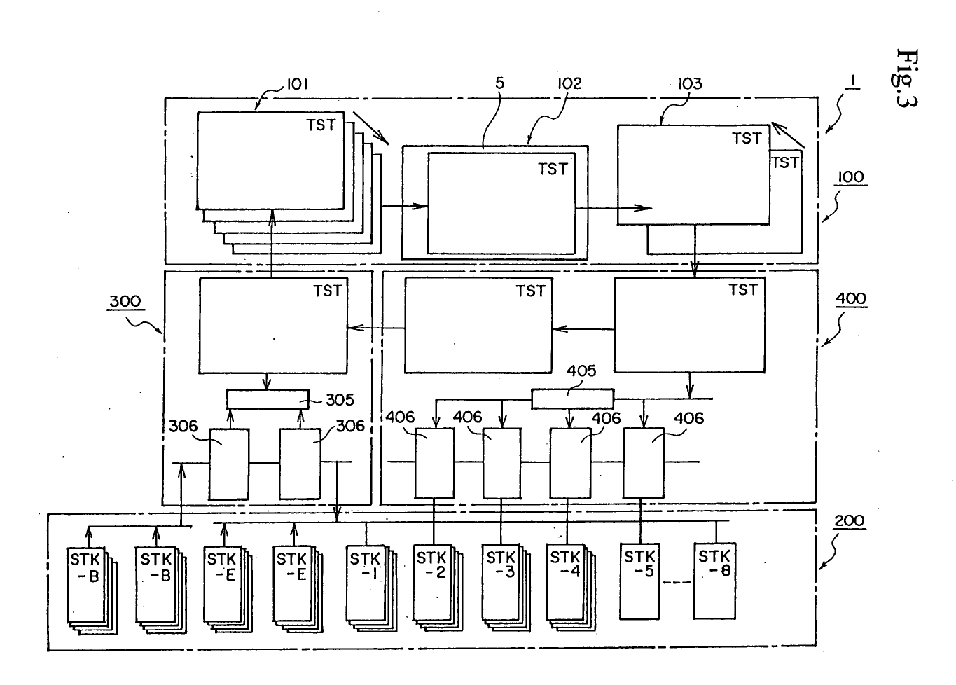

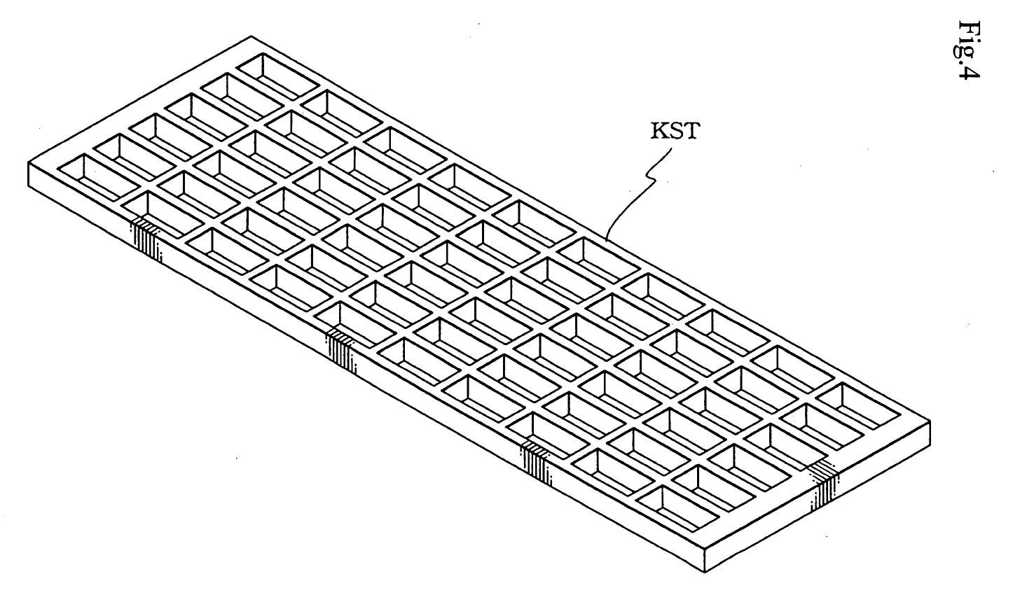

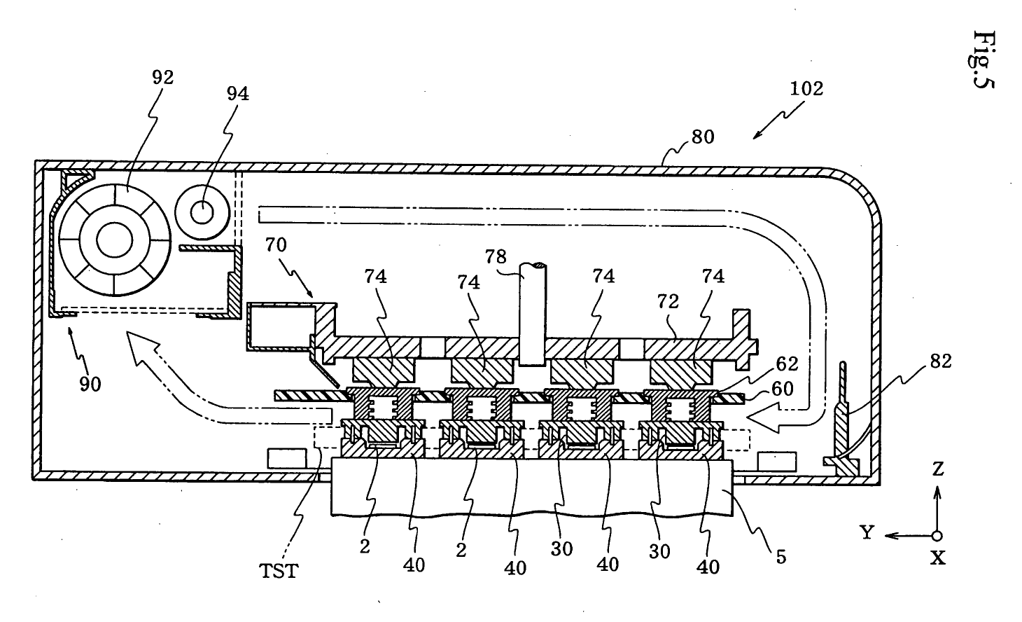

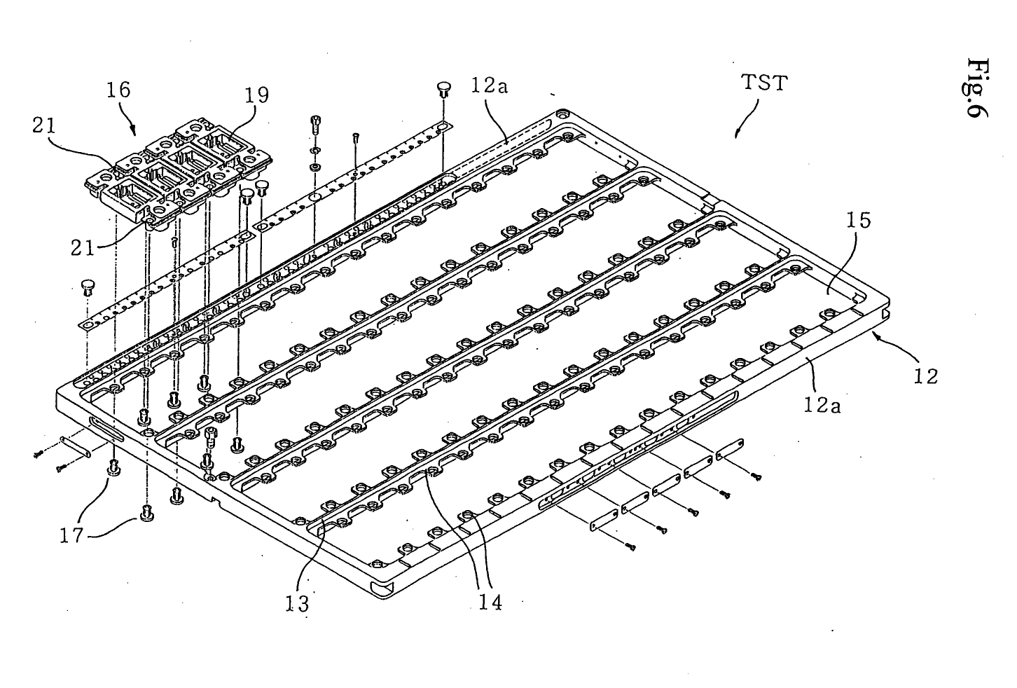

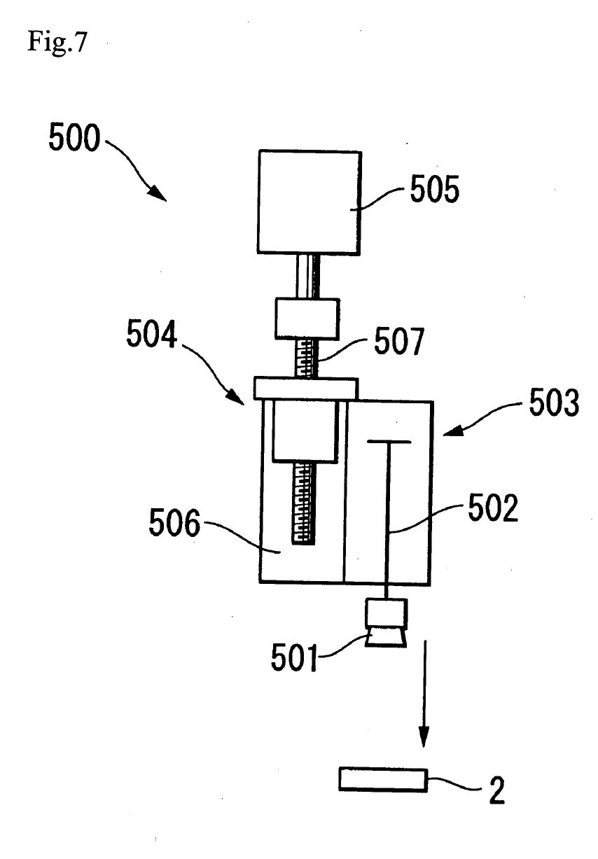

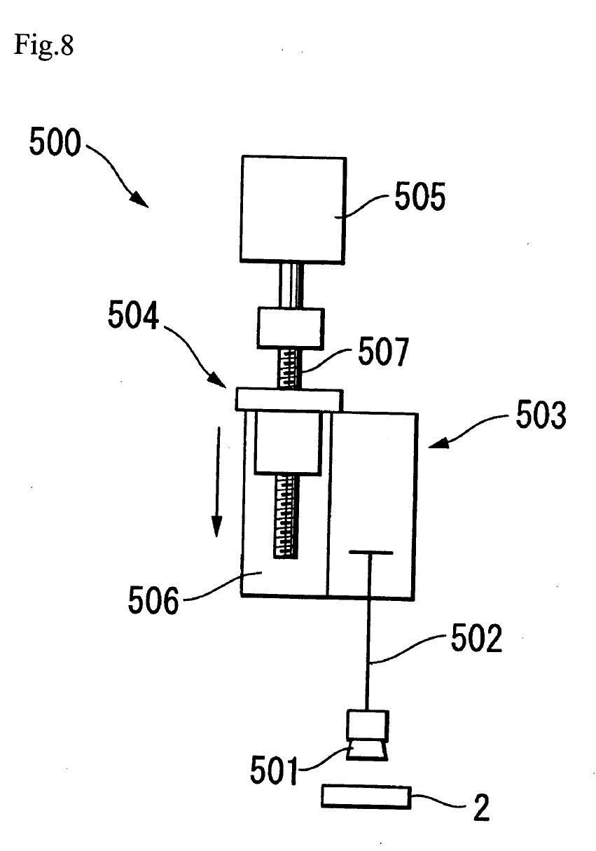

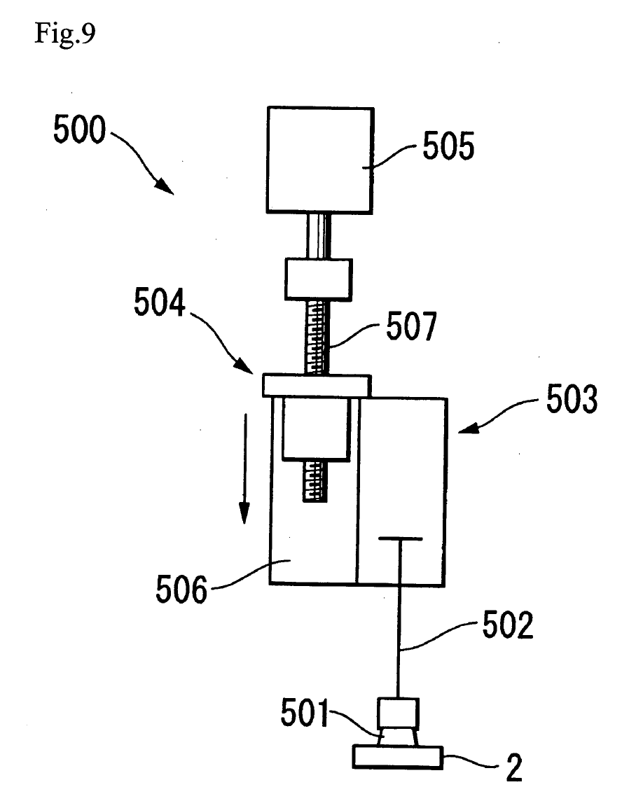

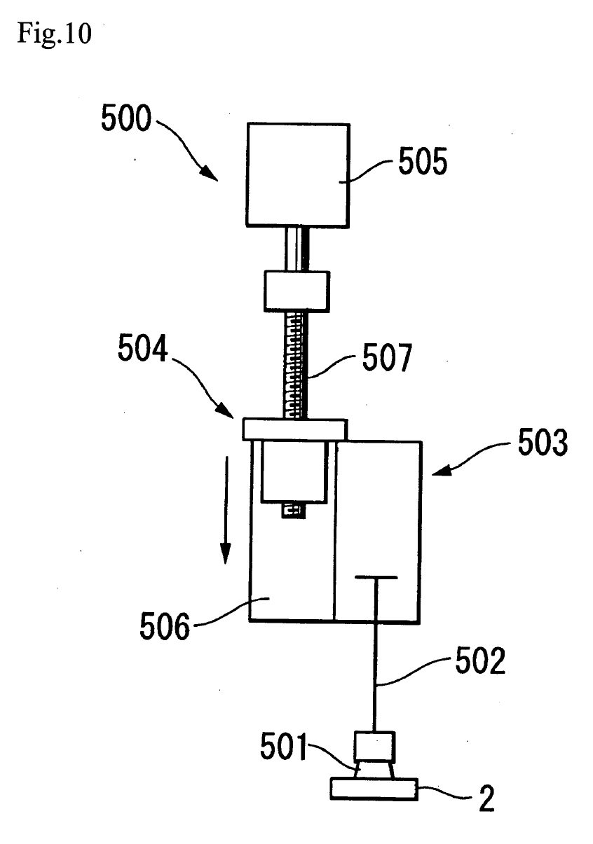

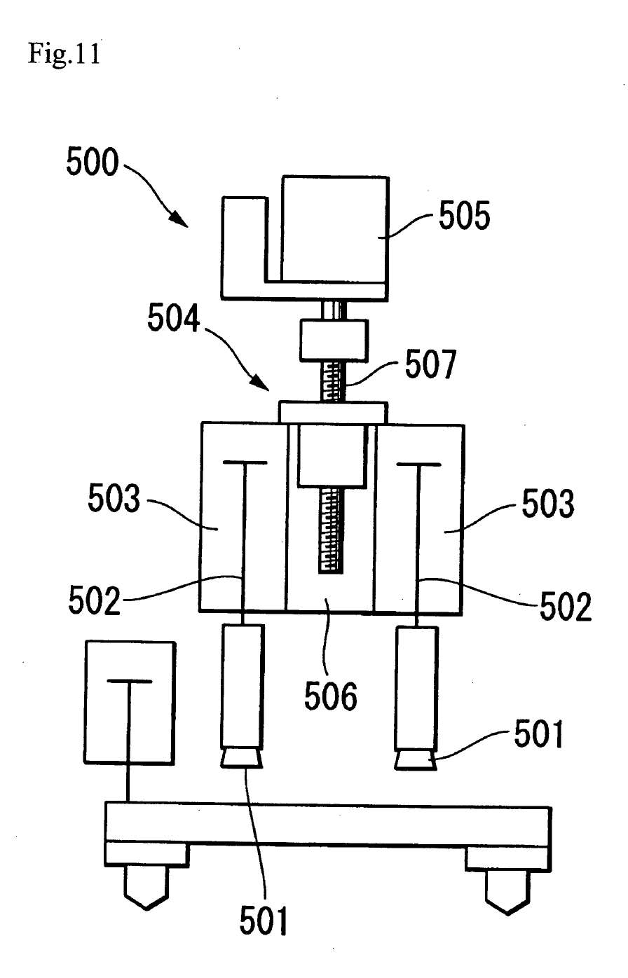

FIG. 1 is an overall view form the side of an IC device testing apparatus including an electronic device handling apparatus (hereinafter, referred to as “a handler”) according to an embodiment of the present invention; FIG. 2 is a perspective view of the handler; FIG. 3 is a flowchart of trays showing a handling method of IC devices to be tested; FIG. 4 is a perspective view showing a customer tray used in the handler; FIG. 5 is a sectional view of a key part inside a test chamber in the handler; FIG. 6 is a partially disassembled perspective view of a test tray used in the handler; FIG. 7 is a view from the side of an example of a pick-and-place mechanism according to an embodiment of the present invention; FIG. 8 is a view from the side showing the pick-and-place mechanism shown in FIG. 7 in a state that a translatory type actuator is operated to lower a suction head to a lower-stroke end; FIG. 9 is a view from the side showing the pick-and-place mechanism shown in FIG. 8 in a state that a servo actuator is operated to lower the suction head together with the translatory type actuator and the suction head is brought to contact with an electronic device; FIG. 10 is a view from the side showing the pick-and-place mechanism shown in FIG. 8 in a state that the servo actuator is operated to lower the suction head together with the translatory type actuator and the suction head is brought to contact with an electronic device; and FIG. 11 is a view from the side showing an example of a pick-and-place mechanism provided with a plurality of suction heads and translatory type actuators.

First, an overall configuration of an IC device testing apparatus provided with a handler according to an embodiment of the present invention will be explained. As shown in FIG. 1, an IC device testing apparatus 10 comprises a handler 1, a test head 5 and a main testing device 6. The handler 1 performs an operation of successively conveying IC devices (an example of electronic devices) to be tested to sockets provided on the test head 5, classifying IC devices finished with the test in accordance with the test results and storing on predetermined trays.

The sockets provided on the test head 5 are electrically connected to the main testing device 6 through a cable 7, connects IC devices mounted detachably on the sockets to the main testing device 6 through the cable 7 and conducts a test on the IC devices by a test electric signal from the main testing device 6.

In the lower portion of the handler 1, a control device for mainly controlling the handler 1 is built in and a space 8 is provided to a part thereof. The test head 5 is arranged in the space 8 in a changeable way, and IC devices can be attached to the sockets on the test head 5 through a through hole formed on the handler 1.

The handler 1 is an apparatus for conducting a test on IC devices as electronic devices to be tested in a higher temperature state (at a high temperature) than the normal temperature and in a lower temperature state (at a low temperature) than the normal temperature. The handler 1 comprises, as shown in FIG. 2, a chamber 100 composed of a soak chamber 101, a test chamber 102 and an unsoak chamber 103. An upper portion of the test head 5 shown in FIG. 1 is inserted to inside of the test chamber 102, as shown in FIG. 5, where IC devices 2 are tested.

Note that FIG. 3 is a view for understanding a handling method of IC devices to be tested in the handler of the present embodiment and partially shows by a plan view members actually arranged aligned in the vertical direction. Therefore, the mechanical (three-dimensional) structure can be understood mainly by referring to FIG. 2.

As shown in FIG. 2 and FIG. 3, the handler 1 of the present embodiment comprises an IC magazine 200 for storing IC devices yet to be tested and storing post-test IC devices by classifying them, a loader section 300 for sending IC devices to be tested sent from the IC magazine 200 to the chamber section 100, a chamber section 100 including the test head, and an unloader section 400 for taking out and classifying post-test IC devices finished with a test in the chamber section 100.

Inside the handler 1, as shown in FIG. 3, IC devices move while being held on a test tray TST, given a high temperature or low temperature thermal stress, tested (inspected) whether they operate appropriately or not, and classified in accordance with the test results.

A large number of the IC devices are held on the customer tray KST shown in FIG. 4 before being set in the handler 1, supplied in that state to the IC magazine 200 of the handler 1 shown in FIG. 2 and FIG. 3, where the IC devices 2 are reloaded from the customer tray KST to the test tray TST (refer to FIG. 6) to be conveyed in the handler 1. Then, post-test IC devices 2 are reloaded from the test tray TST to predetermined customer trays KST in accordance with the test results. This reload of the IC devices 2 is performed by a pick-and-place mechanism 500 provided to a conveyor device in the handler 1.

Below, inside of the handler 1 will be explained individually in detail.

First, a part relating to the IC magazine 200 will be explained.

As shown in FIG. 2, the IC magazine 200 is provided with a pre-test IC stocker 201 for storing pre-test IC devices and a post-test IC stocker 202 for storing IC devices classified in accordance with test results.

These pre-test IC stocker 201 and post-test IC stocker 202 comprise a frame-shaped tray support frame 203 and an elevator 204 capable of entering from under the tray support frame 203 and moving toward the top. The tray support frame 203 supports in it a plurality of stacked customer trays KST, and only the stacked customer trays KST are moved up and down by the elevator 204. Note that the customer tray KST in this embodiment has, as shown in FIG. 4, IC device containers by 10 lines×6 rows.

The pre-test IC stocker 201 shown in FIG. 2 holds stacked customer trays KST loaded with IC devices yet to be tested. The post-test IC stocker 202 holds stacked customer trays KST holding IC devices finished being tested are classified.

As shown in FIG. 2 and FIG. 3, in the present embodiment, two stockers STK-B are provided as the pre-test stocker 201. Next to the stockers STK-B, two empty stockers STK-E to be sent to the unloader section 400 are provided as the post-test IC stocker 202. Still next to them, 8 stockers STK-1, STK-2, . . . STK-8 are provided as the post-test IC stocker 202 and configured to be able to hold IC devices sorted into a maximum of eight classes according to the test results. That is, in addition to classifying IC devices as good and defective, it is possible to divide the good IC devices into ones with high operating speeds, ones with medium speeds, and ones with low speeds and the defective IC devices into ones requiring retesting, etc.

Secondary, a part relating to the loader section 300 will be explained.

The customer tray KST held in the pre-test IC stocker 201 is, as shown in FIG. 2, conveyed by a tray transfer arm 205 provided between the IC magazine 200 and an apparatus substrate 105 from below the apparatus substrate 105 to an opening 306 of the loader section 300. Then, in the loader section 300, IC devices loaded on the customer tray KST are once transferred to a preciser 305 by an X-Y conveyor 304, where pitches of a plurality of (for example, 16) IC devices to be tested are converted to arrangement pitches on the test tray side and mutual positions of the IC devices to be tested are corrected, then, the IC devices transferred to the preciser 305 are again loaded on the test tray TST stopped in the loader section 300 by using the X-Y conveyor 304.

The X-Y conveyor 304 for reloading IC devices to be tested from a customer tray KST to a test tray TST comprises, as shown in FIG. 2, two rails 301 laid over an apparatus substrate 105, a movable arm 302 able to move back and forth (this direction is designated as the Y-direction) between the test tray TST and the customer tray KST by those two rails 301, and a movable head 303 supported by the movable arm 302 and able to move in the X-direction along the movable arm 302.

The movable head 303 of the X-Y conveyor 304 has a pick-and-place mechanism 500 provided with a plurality of (for example, 16) suction heads 501. The suction heads 501 move while drawing air to pick up the IC devices to be tested from the customer tray KST and reload the IC devices to be tested on the test tray TST. Details of the pick-and-place mechanism 500 will be explained later on. Note that the suction heads 501 are connected to a negative-pressure source (not shown) via suction tube paths, and each suction tube path is preferably provided with a suction detection sensor (not shown) which detects whether an IC device to be tested is picked up or not.

Thirdly, a part relating to the chamber 100 will be explained.

The above explained test tray TST is loaded with IC devices to be tested at the loader section 300 and, then, sent to the chamber 100, where a large number of (for example 64) IC devices loaded on the test tray TST are tested under a predetermined temperature condition (for example, −50 to +120° C.).

As shown in FIG. 2, the chamber 100 comprises a soak chamber 101 for giving a thermal stress of an objected high temperature or a low temperature to the IC devices to be tested loaded on the test tray TST, a test chamber 102 wherein the IC devices in a state of being given a thermal stress in the soak chamber 101 are mounted on sockets on the test head, and an unsoak chamber 103 for removing the given thermal stress from the IC deices tested in the test chamber 102.

In the unsoak chamber 103, the IC devices are brought back to the room temperature by ventilation when a high temperature was applied in the soak chamber 101, and brought back to a temperature of a degree of not causing condensation by heating by a hot air or a heater, etc. when a low temperature was applied in the soak chamber 101. Then, the IC devices brought to a normal temperature are taken out to the unloader section 400.

As shown in FIG. 5, a test head 5 is arranged at a lower portion in the test chamber 102 and the test tray TST is transferred to be above the test head 5. Note that the test tray TST is attached with inserts 16 (refer to FIG. 6) holding IC devices 2. In the test chamber 102, all IC devices 2 held by the test tray TST are all together brought to electrically contact with the test head 5, and all IC devices 2 on the test tray TST are tested. On the other hand, the test tray TST finished the test is removed a thermal stress in the unsoak chamber 103 so as to bring the temperature of the IC devices 2 to the room temperature and, then, taken out to the unloader section 400 shown in FIG. 2.

Also, as shown in FIG. 2, at an upper portion of the soak chamber 101 and the unsoak chamber 103 is formed an inlet opening for taking in the test tray TST from the apparatus substrate 105 and an outlet opening for taking out the test tray TST to the apparatus substrate 105, respectively. The apparatus substrate 105 is attached test tray conveyors 108 for taking in and out the test tray TST to and from the openings. The conveyor 108 comprises, for example, a rotation roller, etc. The test tray TST taken out from the unsoak chamber 103 is conveyed to the unloader section 400 by the test tray conveyor 108 provided on the apparatus substrate 105.

FIG. 6 is a disassembled perspective view of the configuration of the test tray TST used in the present embodiment. The test tray TST has a rectangular frame 12, and the frame 12 is provided with a plurality of bars 13 in parallel at regular intervals. On both sides of the bars 13 and inside the sides 12a of the frame 12 in parallel with the bars 13 are respectively formed a plurality of mounting tubs 14 protruding in the longitudinal direction at regular intervals. Each of insert magazines 15 is composed of two mounting tubs 14 facing to each other among the plurality of mounting tubs 14 provided between the bars 13 and between the bars 13 and the sides 12a.

The each of the insert magazines 15 is to hold one insert 16, and the insert 16 is attached to the two mounting tubs 14 in a floating state by using a fastener 17. In the present embodiment, the inserts 16 are, for example, provided by the number of 4×16 to one test tray TST. Namely, the test tray TST in the present embodiment has IC device magazines by the number of 4 lines×16 rows. As a result of holding IC devices 2 to be tested in the inserts 16, the IC devices 2 to be tested are loaded on the test tray TST.

In the insert 16 of the present embodiment, a rectangular recessed IC container 19 for holding an IC device 2 to be tested is formed as shown in FIG. 6. On the center portion of both sides of the insert 16, a guide hole to which a guide pin of a later explained pusher 30 is inserted is formed. At corners on both ends of the insert 16, mounting holes 21 for mounting tubs of a test tray TST are formed.

As shown in FIG. 5, sockets 40 having connection terminals, which are brought to contact with and electrically connected to external terminals of IC devices 2, are fixed on the test head 5. On the sockets 40, pushers 30 for pressing the IC devices 2 against the sockets 40 are provided.

Each pusher 30 is, as shown in FIG. 5, fixed to the lower end of an adopter 62, and each adopter 62 is elastically held by a match plate 60. The match plate 60 is supported by a drive plate 72 so as to position above the test head 5 and to allow the test tray TST to be inserted between the pusher 30 and the socket 40. The pusher 30 held by such a match plate 60 can freely move to the direction of the test head 5 and to the direction of the drive plate 72, that is, in the Z-axis direction.

Note that the test tray TST is transferred from the vertical direction (X-axis) with respect to the paper surface in FIG. 5 to between the pushers 30 and the sockets 40. As the transfer means of the test tray TST inside the chamber 100, a transfer roller, etc. is used. At the time of transferring the test tray TST, a drive plate of the Z-axis drive 70 is raised along the Z-axis direction and a sufficient room is formed between the pushers 30 and the sockets 40 for the test tray TST to be inserted.

As shown in FIG. 5, on the lower surface of a drive plate 72, pressing portions 74 are fixed so as to be able to press the upper surface of the adopter 62. A drive axis 78 is fixed to the drive plate 72 and a motor or other drive source (not shown) is connected to the drive axis 78 for enabling the drive axis 78 to move up and down along the Z-axis direction.

In the present embodiment, as shown in FIG. 5, a temperature adjusting ventilation 90 is mounted inside the airtight casing 80 composing the test chamber 102 in the chamber 100 configured as above. The temperature adjusting ventilation 90 comprises a fan 92 and a heat exchanger 94 and adjusts inside the casing 80 to be in a predetermined temperature condition (a high temperature or a low temperature) by inhaling an air inside the casing by the fan 92 and blowing to inside the casing through the heat exchanger 94 for circulation.

Fourthly, a part relating to the unloader section 400 will be explained.

The unloader section 400 shown in FIG. 2 is provided with X-Y conveyors 404 and 404 having the same configuration with that of the X-Y conveyor 304 provided to the loader section 300. Accordingly, each of the X-Y conveyors 404 and 404 is provided with a movable head 403 and a pick-and-place mechanism 500 in the same way as the X-Y conveyor 304. From the test tray TST conveyed out to the unloader section 400, IC devices are sorted based on test results, such as good/defective sort and rank sort, and reloaded to corresponding customer trays KST by the X-Y conveyors 404 and 404.

As shown in FIG. 2, a device substrate 105 of the unloader section 400 is provided with a pair of windows 406 and 406 arranged so that the customer trays KST carried to the unloader section 400 can be brought close to the upper surface of the device substrate 105 from below.

An elevator 204 for elevating or lowering a customer tray KST is provided below the respective openings 406, where a customer tray KST becoming full after being reloaded with the post-test IC devices is placed and lowered and the full tray is passed to the tray transfer arm 205.

Fifthly, the pick-and-place mechanism 500 will be explained.

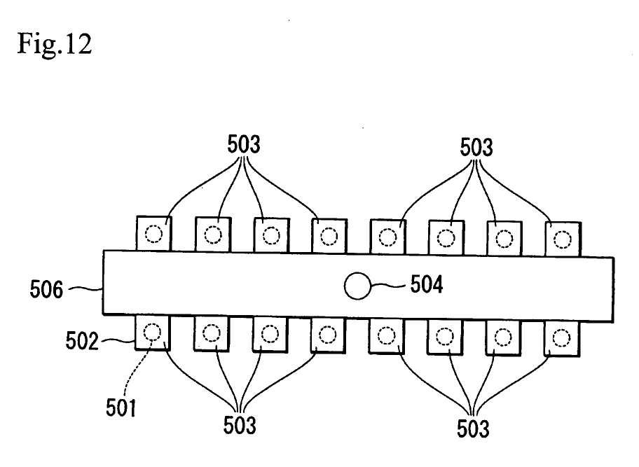

As explained above, the movable heads 303 and 403 of the X-Y conveyors 304 and 404 are provided with a pick-and-place mechanism 500 having a plurality of (for example, 16) suction heads 501. The pick-and-place mechanism 500 is a mechanism for moving the suction heads 501 up and down to pick up IC devices 2 by the suction heads 501 and to mount on predetermined positions. In the present specification, an operation of picking up the IC devices 2 by suction by the suction heads 501 is called “picking”, an operation of releasing the picked up IC devices 2 and mounting at predetermined positions is called “placing”, and these operations are collectively called “pick-and-place”. The pick-and-place mechanism 500 in the present embodiment comprises, as shown in FIG. 7, a translatory type actuator 503 and a servo actuator 504. Note that, as shown in FIG. 12, two or more (for example, 16) translatory actuator 503 are provided, however, it is omitted in FIG. 7.

The translatory type actuator 503 is an elevator device capable of driving at a high speed in accordance with a relatively large elevating amount and is a device for elevating/lowering the support member 502 supporting the suction heads 501 between the upper stroke end and the lower stroke end based on a drive fluid source (not shown) from the outside. As the translatory actuator 503 used in the pick-and-place mechanism 500 in the present embodiment, those having a light and compact body and being inexpensive are preferable, and those capable of displacing a position of the suction heads 501 between the upper stroke end and the lower stroke end are normally used. For example, in the present embodiment, a piston rod is used as the support member 502 and a cylinder device which moves the piston rod back and forth is used as the translatory type actuator 503. In this case, the cylinder device may be a hydraulic cylinder device or a pneumatic cylinder device. When the piston rod is moved back and forth by such a cylinder device, it is preferable in the point that the suction heads 501 can be swiftly displaced between two positions. According to the translatory actuator 503, the support member 502 can be moved at a high speed in a main elevating/lowering range of “pick-and-place”, consequently, there is an advantage that move time of the suction heads 501 in this range can be shortened.

Note that the cylinder device explained here is just one preferable example of the translatory type actuator 503. As the translatory type actuator 503, a variety of actuators capable of linearly moving the support member 502 and the suction heads 501 between both stroke ends can be used. For example, a solenoid, etc. may be used other than the cylinder devices.

The servo actuator 504 is an elevator device which drives at a low speed in accordance with a relatively small elevating/lowering amount and is a device for elevating/lowering the support member 502 and the suction heads 501 together with the translatory type actuator 503. It is more preferable that the servo actuator 504 is capable of controlling to stop at any elevating/lowering position and controlling the elevating/lowering speed. For example, in the present embodiment, a ball screw and a drive motor 505 for driving it are used as the servo actuator 504. According to such a device, a lowering speed can be controlled to be reduced immediately before suction pads at tips of the suction heads 501 contact with IC devices 2, consequently, an excessive impact load on the IC devices 2 can be prevented.

The pick-and-place mechanism 500 of the present embodiment comprises the above explained translatory type actuator 503 and servo actuator 504, so that an impact load on IC devices 2 can be reduced as much as possible, and a decline of throughput of an IC device transfer can be prevented by shortening a move time of the suction heads 501.

Here, a height of the IC devices 2 may vary every time a kind of devices changes. Particularly, as to device kinds relating to production of a variety of kinds in small amounts, a height of IC devices 2 frequently changes. Therefore, a lower stop position of the servo actuator has to be set for each of the device kinds having different heights. As the setting method, there are a method of setting a fixed set values based on heights of the IC devices 2 and a method of automatically obtaining set values as below. Note that each of the suction heads 501 is provided with a suction detection sensor for detecting whether an IC device is picked up or not.

When setting the lower stop position at the time of sucking (picking up) the IC devices 2, the servo actuator 504 is lowered at a low speed while detecting suction by the suction detection sensor, and when the suction heads 501 suck the IC devices 2, the suction state is detected. Based on the detection, a position where suction is surely made and a pressing stress is not given to the IC devices 2 is set as the set value of the lowering stop position at the time of picking. On the other hand, the lower stop position at the time of mounting (placing) the IC devices 2 is set to the set value obtained as explained above or a set value obtained by adding/subtracting a desired offset amount to/from the value. As a result, the suction heads 501 can be automatically set at an optimal lowering stop position for IC devices 2 having different thicknesses depending on the device kinds.

Information on the set value of the lower stop position obtained as above is preferably stored in a memory device with all picking positions and placing positions of the X-Y conveyors 304 and 404. Also, the above set value information is preferably obtained regularly and, thereby, arising of unevenness and deterioration of respective suction heads 501 can be specified based on changes of the obtained set value information with time.

In the case of the present embodiment, as shown in FIG. 7, etc., a frame 506 formed to be one body with the translatory type actuator 503 is provided, and a nut of the ball screw is provided to the frame 506. Also, a screw bar 507 connected to a rotation axis of the drive motor 505 engages with the nut. Accordingly, by rotating the screw bar 507, the frame 506, the translatory type actuator 503 and the suction heads 501 can be moved up and down at the same time. In that case, the frame 506 is guided by a not shown guide in the vertical direction.

Note that the case of using a ball screw as an example of the servo actuator 504 was taken as an example here, however, this is just a preferable one example of the servo actuator 504. The point is that it is sufficient if an impact load can be reduced sufficiently at the time that the suction heads 501 contact with the IC devices 2 and the suction heads 501 can stop at a desired position. Therefore, for example, a combination of a pulley and a belt, a combination of a rack and a pinion, and a linear actuator, etc. may be used as the servo actuator 504 in the pick-and-place mechanism 500 in the present embodiment.

Next, an operation of picking and placing by the above explained pick-and-place mechanism 500 to pick up IC devices 2 by suction and control of the operation will be explained. The operation of picking and placing is performed at the time of reloading pre-test IC devices 2 from a customer tray KST to a preciser 305, reloading from the preciser 305 to a test tray TST, and reloading post-test IC devices 2 from the test tray TST to the customer tray KST (reloading from the test tray TST to preciser 405 and, then, from the preciser 405 to the customer tray KST in certain instances).

First, the X-Y conveyors 304 and 404 are activated to move the pick-and-place mechanism 500 to an initial position (over a customer tray KST or a test tray TST). At the initial position, as shown in FIG. 7, the suction heads 501 position immediately above IC devices 2 to be conveyed. Note that the suction head 501 are in a standby state at the most distant position from the IC devices 2 before performing the pick-an-place operation. Namely, the servo actuator 504 is in a state of elevating the frame 506 and the translatory type actuator 503 to the uppermost position, and the translatory type actuator 503 is in a state of elevating the support member 502 and the suction heads 501 to the upper stroke end.

Here, a position of the lower stroke end of the suction heads 501 and the support member 502 which move up and down in a certain stroke width is, as shown in FIG. 8, set at a position where the suction heads 501 stop at least short of the IC devices 2. To put it in a different way, a distance between the suction heads 501 and the IC devices 2 in the standby state is set to be slightly longer than the stroke width of the translatory type actuator 503. Therefore, the suction heads 501 do not contact with the IC devices 2 only by moving the support member 502 and the suction heads 501 in the standby state to the lower stroke end by the translatory type actuator 503 (refer to FIG. 8). Such setting can be realized by suitably adjusting a length of the support member 502 in the vertical direction or by adjusting a vertical position of the pick-and-place mechanism 500.

Note that, when setting as above, it does not matter which of a stroke width of the translatory type actuator 503 and a stroke width of the servo actuator 504 is wider, and the both may be set to a variety of values as far as satisfying the above conditions. For example, the stroke width of the servo actuator 504 may be set larger than that of the translatory type actuator 503, such that the stroke width of the translatory type actuator 503 is 10 mm and that of the servo actuator 504 is 15 mm. The opposite case is also possible.

Next, the support member 502 and the suction heads 501 are lowered to the lower stroke end by the translatory type actuator 503. At this time, as explained above, the suction heads 501 stop immediately before contacting the IC devices 2 to be in a state of positioning slightly upper than the IC devices 2 (refer to FIG. 8). After that, the servo actuator 504 is activated by driving the drive motor 505 to lower the support member 502 and the suction heads 501 together with the translatory type actuator 503 while controlling the speed (refer to FIG. 9). At this time, it is preferable to reduce the lowering speed particularly from a position a little short of the lower stop position where the suction heads 501 contact with the IC devices 2. As a result, an impact load acting on the IC devices 2 at the time of contacting can be reduced. After that, suction by the suction heads 501 starts and the IC devices 2 are picked up by suction by the suction heads 501.

Note that, in the case where a suction detection sensor is provided, when suction of an IC device 2 is not detected for some reason, as shown in FIG. 10, it is possible to lower the suction head 501 at a furthermore lower speed by the drive motor 505 to pick up the IC device 2 by suction. Due to this, suction errors can be reduced.

When the suction heads 501 suck the IC devices, the servo actuator 504 is rotated in the reverse direction to elevate the suction heads 501 and raise the IC devices 2. Then, the X-Y conveyors 304 and 404 are activated to move the IC devices 2 picked up by the suction heads 501 to a predetermined position (above a preciser 305 or a customer tray KST).

After the transfer, the servo actuator 504 is operated again and the IC devices 2 together with the translatory type actuator 503 are lowered while controlling the speed. Then, at the moment that the IC devices 2 land, suction by the suction heads 501 stops and the IC devices 2 are mounted (placed) at predetermined positions.

After placing the IC devices 2 at the predetermined positions, the servo actuator 504 is operated to raise the suction heads 501 and a pick-and-place operation is performed on next IC devices 2. When all of targeted IC devices 2 are subjected to the pick-and-place operation as explained above, the translatory type actuator 503 is activated to elevate the support member 502 and the suction heads 501 to the upper stroke end and the pick-and-place mechanism 500 is returned to the initial position.

Note that, up until here, an explanation was made on an embodiment wherein one suction head 501 is provided to one pick-and-place mechanism 500. However, in actually, a plurality of suction heads 501 are preferably provided to one pick-and-place mechanism 500 as shown in FIG. 11 and FIG. 12. In that case, the number of the suction heads 501 may be a variety of values, for example, a total of 16 by arranging 8 on each of two rows, etc. in accordance with a shape of a test tray TST.

FIG. 11 and FIG. 12 show an example of a pick-and-place mechanism 500 provided with a plurality of suction heads 501. In this pick-and-place mechanism 500, the frame 506 is made larger than that in the above explained case, and a plurality of translatory type actuators 503, support members 502 and suction heads 501 are provided to the frame 506.

According to the pick-and-place mechanism 500 wherein one servo actuator 504 is provided with a plurality of support members 502, translatory type actuators 503 and suction heads 501 as explained above, costs of an apparatus required per one IC device 2 can be reduced and, moreover, the apparatus weight can be reduced for that amount comparing with a pick-and-place mechanism wherein a plurality of suction heads and support members are moved up and down by the corresponding number of servo actuators. Furthermore, an installation space is reduced by an amount of a reduction of numbers of necessary servo actuators 504 and drive motors 505, consequently, the handler 1 can be downsized.

Also, according to the above explained pick-and-place mechanism 500, in addition to elevating/lowering all suction heads 501 simultaneously by the servo actuator 504, each suction head 501 can be also individually elevated/lowered by the translatory type actuator 503. According to such a pick-and-place mechanism 500, when targeted IC devices 2 do not exist, it is possible to leave corresponding suction heads 501 in a standby state. In that case, there is an advantage that a wasteful operation of translatory type actuators 503 at the position can be prevented. Alternately, even when a part of the plurality of suction heads 501 are in a state of holding IC devices 2 by suction, another IC device 2 can be picked up by suction by elevating/lowering only another suction head 501.

The embodiments explained above are described to facilitate understanding of the present invention and is not to limit the present invention. Accordingly, respective elements disclosed in the above embodiments include all design modifications and equivalents belonging to the technical scope of the present invention.

### INDUSTRIAL APPLICABILITY

The pick-and-place mechanism of an electronic device, an electronic device handling apparatus and a suction method of an electronic device are useful to reduce an impact load acting on the electronic device when picking up the electronic device by suction by the suction head.

1. A pick-and-place mechanism of an electronic device for picking up an electronic device by suction by a suction head, moving the same and, then, placing the same at a predetermined position in an electronic device testing apparatus, comprising:
a translatory type actuator for moving a support member supporting said suction head up and down between an upper stroke end and a lower stroke end; and
a servo actuator for moving said support member and said suction head together with said translatory type actuator up and down and capable of controlling a speed of at least an operation in the downward direction.

2. The pick-and-place mechanism of an electronic device as set forth in claim 1, wherein
said servo actuator operates to bring said suction head contact with said electronic device by lowering said support member and said suction head together with said translatory type actuator while controlling the speed in a state that said support member is positioned at a lower stroke end.

3. The pick-and-place mechanism of an electronic device as set forth in claim 1, comprising a plurality of said suction heads.

4. The pick-and-place mechanism of an electronic device as set forth in claim 3, wherein said support member and said translatory type actuator are provided to each of said plurality of suction heads.

5. The pick-and-place mechanism of an electronic device as set forth in claim 1, wherein said support member is a piston rod, and said translatory type actuator is a cylinder device which makes said piston rod move back and forth.

6. The pick-and-place mechanism of an electronic device as set forth in claim 1, wherein said servo actuator comprises a ball screw and a motor for driving the ball screw.

7. An electronic device handling apparatus capable of handling an electronic device for conducting tests on said electronic device, comprising the pick-and-place mechanism as set forth in any one of claims 1 to 6.

8. A suction method of an electronic device when picking up an electronic device by suction by a suction head in an electronic device testing apparatus, comprising steps of:
setting a position of a lower stroke end of a support member, which supports said suction head and is capable of moving straight, at a position where said suction head stops short of said electronic device;
lowering said support member to the lower stroke end by a translatory actuator;
then, bringing said suction head contact with said electronic device while reducing an impact at the time of contacting by lowering said support member and said suction head together with said translatory type actuator by a servo actuator while controlling the speed; and
picking up said electronic device by said suction head.

9. A suction method of an electronic device when picking up an electronic device by suction by a suction head in an electronic device testing apparatus, comprising steps of:
setting a position of a lower stroke end of a piston rod, which supports said suction head, at a position where said suction head stops short of said electronic device;
lowering said piston rod to the lower stroke end by a cylinder device;
then, bringing said suction head contact with said electronic device while reducing an impact at the time of contacting by lowering said piston rod and said suction head together with said cylinder device by a ball screw while controlling the speed; and
picking up said electronic device by said suction head.

10. A pick-and-place mechanism of an electronic device capable of picking up an electronic device by suction and mounting at a predetermined position by a suction head in an electronic device testing apparatus, comprising:
a first drive mechanism which supports said suction head and is capable of moving said suction head to a first position, where said electronic device is picked up by suction or mounted, and to a second position being away from said first position; and
a second drive mechanism which supports said first drive mechanism and is capable of successively moving said first drive mechanism by a predetermined move amount and stopping the same.

11. The pick-and-place mechanism as set forth in claim 10, wherein said first drive mechanism is a translatory type actuator capable of stroke moving said suction head between a lower stroke end as said first position and an upper stroke end as said second position.

12. The pick-and-place mechanism as set forth in claim 11, wherein said second drive mechanism is a servo actuator having a drive axis, and said first drive mechanism is attached to a drive axis of said second drive mechanism.

13. The pick-and-place mechanism as set forth in claim 10, wherein there are a plurality of said first drive mechanisms, said second drive mechanism supports said plurality of first drive mechanisms, and said plurality of first drive mechanisms can move simultaneously by driving said second drive mechanism.

14. The pick-and-place mechanism as set forth in claim 10, wherein
said suction head or a tube path for drawing connected to said suction head is provided with a suction detection sensor capable of detecting whether an electronic device is picked up by the suction head or not;
said pick-and-place mechanism is driven to pick up an electronic device by suction by said suction head, said suction detection sensor specifies a position where suction of said electronic device is detected, and a stop position of said second drive mechanism can be set based on said specified detection position.

15. An electronic device testing apparatus comprising a pick-and-place mechanism of an electronic device capable of picking up an electronic device by suction and mounting the same at a predetermined position by a suction head, wherein
said pick-and-place mechanism comprises
a first drive mechanism which supports said suction head and is capable of moving said suction head to a first position, where said electronic device is picked up by suction or mounted, and to a second position being away from said first position; and
a second drive mechanism which supports said first drive mechanism and is capable of successively moving said first drive mechanism by a predetermined move amount and stopping the same.
